(19) United States
(12) Patent Application Publication
(10) Pub. No.: US 2014/0090702 A1
(43) Pub. Date: Apr. 3, 2014

(54) BUS BAR FOR A SOLAR CELL

(71) Applicant: SUNIVA, INC., Norcross, GA (US)

(72) Inventors: Atul Gupta, Dunwoody, GA (US); Vinodh Chandrasekaran, Suwanee, GA (US); John Roberts, Suwanee, GA (US)

(73) Assignee: Suniva, Inc., Norcross, GA (US)

(21) Appl. No.: 13/631,554

(22) Filed: Sep. 28, 2012

(51) Int. Cl. H01L 31/0224

(52) U.S. Cl. 136/256

(57) ABSTRACT

Various embodiments of the present invention are directed to a reduced-area bus bar for collecting current from contacts on the surface of a solar cell. According to various embodiments described herein, a reduced-area bus bar is provided having a width that varies at various points along its longitudinal axis. In particular, the larger width portions of the reduced-area bus bar are configured to provide sufficient pull strength when an interconnecting ribbon is soldered along the bus bar, while the smaller width portions of the reduced-area bus bar enable a reduction in the material required to form the bus bar. Additionally, various embodiments are contemplated in which the reduced-area bus bar comprises a series of segments disposed in a spaced-apart relationship along the bus bar's longitudinal axis.

### BACKGROUND OF THE INVENTION

1. Field of the Invention

Various embodiments of the present invention described herein generally relate to solar cells; particularly solar cells with reduced-area bus bars.

2. Description of Related Art

In basic design, a solar cell is composed of a material such as a semiconductor substrate that absorbs energy from photons to generate electricity through the photovoltaic effect. When photons of light penetrate into the substrate, the energy is absorbed and an electron previously in a bound state is freed. The released electron and the previously occupied hole are known as charge carriers.

The substrate is generally doped with p-type and n-type impurities to create an electrical field inside the solar cell at a p-n junction. In order to use the free charge carriers to generate electricity, the electrons and holes are separated by the electrical field at a p-n junction. The free electrons are then be collected by the electrical contacts on the n-type layer and the holes are collected by electrical contacts on the p-type layer. The charge carriers that do not recombine are then available to power a load.

Solar cells of this type are commonly connected together in groups to produce a solar module. A typical approach involves providing one or more bus bars on the p-type and n-type surfaces of a first solar cell to collect current from the first cell's contacts. The first cell's p-type bus bar can then be connected a second solar cell's n-type bus bar using an interconnecting medium, such as a metallic ribbon soldered to the appropriate bus bars. As a result, the first and second solar cells are connected in series and—using the same approach for all cells in the module—charge carriers from each cell are collectively made available to power a load.

However, typical solar cell bus bars are formed from expensive conductive materials, such as silver, nickel, or Titanium/Pd/Ag. As cost and performance are major factors in the viability of solar cells as widely used energy producing devices, there is a need in the art for an improved bus bar for a solar cell that reduces the usage of expensive conducting materials while enabling high levels of electrical and mechanical performance.

### BRIEF SUMMARY OF THE INVENTION

Various embodiments of the present invention are directed to a solar cell having a front surface and a back surface. In various embodiments, the solar cell comprises: a semiconductor wafer; one or more contacts positioned on at least one of the front surface and back surface of the solar cell, the contacts being in electrical communication with the solar cell; and at least one bus bar disposed on the at least one of the front surface and back surface in electrical communication with the one or more contacts and configured for collecting current from the one or more contacts. According to various embodiments, the bus bar is oriented along a generally longitudinal axis and the width of the bus bar varies at points along the longitudinal axis. In addition, in various embodiments, the bus bar defines: a first portion having a first width; a second portion positioned adjacent the first portion, the second portion having a second width that is less than the first width; a third portion positioned adjacent the first portion opposite the second portion, the third portion having a third width that is less than the first width; and a fourth portion positioned adjacent the third portion, the fourth portion having a fourth width that is greater than the third width.

In addition, various embodiments of the present invention are directed to a solar cell having a front surface and a back surface, the solar cell comprising: a semiconductor wafer; a plurality of contacts positioned on at least one of the front surface and back surface of the solar cell in a spaced-apart relationship, the contacts being in electrical communication with the solar cell; and at least one bus bar disposed on the at least one of the front surface and back surface in electrical communication with the one or more contacts and configured for collecting current from the one or more contacts. According to various embodiments, the bus bar is oriented along a generally longitudinal axis and comprises a plurality of bus bar segments disposed in a spaced-apart relationship along the longitudinal axis.

### BRIEF DESCRIPTION OF THE SEVERAL VIEWS OF THE DRAWINGS

Reference will now be made to the accompanying drawings, which are not necessarily drawn to scale, and wherein:

FIG. 1 shows a cross-sectional view of a solar cell according to one embodiment of the present invention;

FIG. 2 shows a plan view of the front surface of a solar cell having a plurality of reduced-area bus bars according to one embodiment of the present invention;

FIG. 3 shows a plan view of a portion of a reduced-area bus bar according to one embodiment of the present invention;

FIG. 4 shows a detailed plan view of a portion of the bus bar of FIG. 3 disposed on the front surface of a solar cell according to one embodiment of the present invention;

FIG. 5 shows a plan view of a portion of a reduced-area bus bar according to another embodiment of the present invention;

FIG. 6 shows a plan view of a portion of a reduced-area bus bar according to yet another embodiment of the present invention;

FIG. 7 shows a plan view of a portion of a reduced-area bus bar according to yet another embodiment of the present invention;

FIG. 8 shows a plan view of a portion of a reduced-area bus bar according to yet another embodiment of the present invention;

FIG. 9 shows a plan view of a portion of a reduced-area bus bar according to yet another embodiment of the present invention;

FIG. 10 shows a detailed plan view of a portion of the bus bar of FIG. 9 disposed on the front surface of a solar cell according to one embodiment of the present invention;

FIG. 11 shows a plan view of a portion of a reduced-area bus bar according to yet another embodiment of the present invention;

FIG. 12 shows a detailed plan view of a portion of the bus bar of FIG. 11 disposed on the front surface of a solar cell according to one embodiment of the present invention;

FIG. 13 shows a detailed plan view of a portion of a reduced-area bus bar disposed on the front surface of a solar cell according to another embodiment of the present invention;

FIG. 14 shows a detailed plan view of a portion of a reduced-area bus bar disposed on the front surface of a solar cell according to yet another embodiment of the present invention;

FIG. 15 shows a detailed plan view of a portion of a reduced-area bus bar disposed on the front surface of a solar cell according to yet another embodiment of the present invention; and

FIG. 16 shows a detailed plan view of a portion of a reduced-area bus bar disposed on the front surface of a solar cell according to yet another embodiment of the present invention.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art Like numbers refer to like elements throughout.

As used herein, embodiments in which a first element is described to be “overlying,” “over,” or “above” a second element may generally be taken to signify that the first element is closer to the primary illuminated surface or primary illumination source. For example, if a first element is said to be overlying a second element, the first element may be closer to the primary illumination source. Similarly, embodiments in which a first element is described to be “underlying,” “under,” and “below” a second element may generally be taken to signify that the first element is further from the primary illumination source. For example, if a first element is said to be underlying a second element, the first element may be further from the sun. It should be noted that, in various embodiments, forms of secondary illumination, such as light returning to the device from a reflective surface located behind or beyond the device after the light originating from a primary illumination source has passed through or around the device, may be considered separate from the primary illumination source.

### Overview

Various embodiments of the present invention are directed to a solar cell having an improved bus bar. Generally, solar cell bus bars function to collect current from a plurality of contacts on the front or back surface of a cell. On a surface that includes a plurality of contact lines (e.g., a contact grid), one or more continuous, linear bus bars are frequently provided. Typically, the width of the bus bar is dictated by the requirement that it not only provide a conductive medium for collecting current from the contacts, but that it also provide a solderable surface to which an interconnecting ribbon may be soldered. In various embodiments, the ribbon may be formed, for example, from metallic copper and may be coated with tin (or another solderable material). The ribbon will also generally have a width sufficient to provide a relatively low series resistance in order to effectively carry current from one solar cell to another. To connect a pair of solar cells in series, the ribbon may be soldered along the length of the bus bar.

In order to ensure the reliability of the solar module, the inventors have recognized that the soldered connection between ribbon and the bus bar should have a high pull strength to ensure the ribbon is not disconnected from the bus bar (e.g., by inadvertent picking of the ribbon during manufacturing or use). However, the inventors have also recognized that is desirable to provide a bus bar formed from reduced amounts of conductive material (e.g., reduced silver paste) in order to minimize the cost of an associated solar cell. According to various embodiments described herein, the inventors have devised a reduced-area bus bar having a width that varies at various points along its longitudinal axis. In particular, the inventors have recognized that the larger width portions of the reduced-area bus bar provide sufficient pull strength when a ribbon is soldered along the bus bar, while the smaller width portions of the reduced-area bus bar enable a reduction in the material required to form the bus bar.

As described in greater detail below, various embodiments of the reduced-area bus bar described herein provide reduced cost solar cell without sacrificing significant cell performance or reliability. Exemplary embodiments will now be described in greater detail below.

### Solar Cell

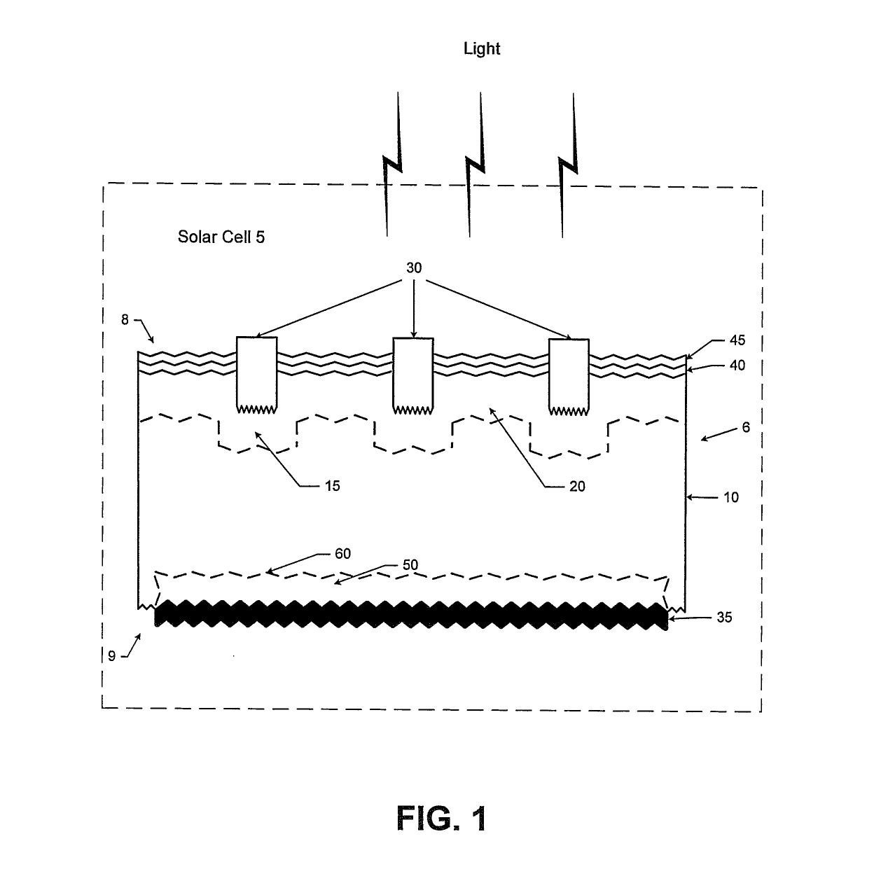

FIG. 1 illustrates a solar cell 5 according to one embodiment of the present invention. In the illustrated embodiment of FIG. 1, the solar cell 5 comprises a semiconductor wafer having three main semiconductor regions: a base layer 10, a front surface layer 15, 20, and a back surface layer 50. In various embodiments, the front surface layer 15, 20 and the back surface layer 50 may be more heavily doped than the base layer 10. In addition, the front surface layer 15, 20 and the back surface layer 50 may have opposite conductivity types. For example, in embodiments where the front surface layer 15, 20 is doped to be n-type, the back surface layer 50 may be doped to be p-type. In such embodiments, the base layer 10 may comprise the portion of the original substrate which has not been further doped (i.e. to form the front and back surface layers) during the process of manufacturing the solar cell 5.

According to various embodiments, the solar cell 5 may be formed of a semiconductor substrate. The substrate may be composed of silicon (Si), germanium (Ge) or silicon-germanium (SiGe) or other semiconductive material, or may be formed from a combination of such materials. In the case of monocrystalline substrates, the semiconductor substrate may be grown from a melt using Float Zone (FZ) or Czochralski (Cz) techniques. The resulting mono-crystalline boule may then be sawn into wafers to form the substrates. In other embodiments, the substrate can be multi-crystalline, which may be less expensive than monocrystalline substrates.

The front 8 and back 9 surfaces of the substrate may define pyramidal structures created by their treatment with a solution of potassium hydroxide (KOH) and isopropyl alcohol (IPA) during an anisotropic etching process. In various embodiments, the presence of these structures increases the amount of light entering the solar cell 5 by reducing the amount of light that is lost by reflection from the front surface 8. The pyramidal structures on the back surface 9 may be fully or partially destroyed during formation of a back contact by alloying aluminum with silicon.

In the illustrated embodiment of FIG. 1, the substrate may be doped with impurities of a first conductivity type to create the base layer 10. If the substrate is composed of silicon (Si), germanium (Ge) or silicon-germanium (Si—Ge), the base layer 10 may be doped with boron (B), gallium (Ga), indium (In), aluminum (Al), or other suitable elements to induce p-type conductivity, thereby forming a p-type base layer 10. In other embodiments, the substrate may be doped with phosphorus (P), antimony (Sb), arsenic (As) or other suitable elements to induce n-type conductivity, thereby forming an n-type base layer 10. N-type substrates are generally immune to light induced degradation (LID), which may lead to a loss of efficiency ranging from 1 to 4% relative in p-type substrates, when exposed to a light source.

In certain embodiments, a front surface layer may be formed by introducing dopant into the front surface of the substrate, for example by diffusion, ion implantation, or the like. The dopant may be of an n-type conductivity or p-type conductivity. In embodiments where the conductivity type of the front surface layer is the same as the base layer, the front surface layer may act as a front surface field layer. In other embodiments where the conductivity type of the front surface layer is opposite the conductivity type of the base layer, the front surface layer may act as an emitter layer. According to certain embodiments, the front surface layer may either be a substantially uniform layer or a selective front surface layer. In the illustrated embodiment of FIG. 1, a selective front surface layer may be made up of heavily doped selective regions 15 and lightly doped field regions 20. According to embodiments where the front surface layer comprises a selective emitter, a p-n junction may be formed at the interface between the base layer 10 and the doped regions 15, 20.

In the embodiment of FIG. 1, the front surface of the doped regions 15, 20 of the front surface layer and back surface of the base layer 10 represent a discontinuity in their crystalline structures, and dangling chemical bonds are present at these exposed surfaces. To prevent the dangling bonds from annihilating charge carriers, in some embodiments, one or more passivating layers may be formed on these surfaces. For example, as shown in FIG. 1, a front passivation layer 40 may contact the front surface of the doped regions 15, 20 of the front surface layer and, optionally, a passivation layer (not shown) may be formed along the sides and on the back surface of the exposed base layer 10. The passivation layers may comprise a dielectric material such as silicon dioxide (SiO₂) for a silicon substrate, or an oxide of another semiconductor type, depending upon the composition of the substrate. The passivation layers may have thicknesses in a range from 5 to 150 nanometers. Additionally, in certain embodiments, the front passivation layer 40 formed on the front surface layer and the optional passivation layer formed on the sides and back surface of the exposed base layer 10 may advantageously produce a high-quality, dielectric-passivated surface, for example when capped with a silicon nitride layer.

As shown in FIG. 1, an antireflection layer 45 is also formed on the front passivation layer 40 on the front surface of the doped regions 15, 20 of the front surface layer. The antireflection layer 45 may be composed of silicon nitride (SiNₓ), aluminum oxide (Al₂O₃), titanium oxide (TiO₂), magnesium fluoride (Mg₂F), zinc oxide (ZnO), zinc sulfide (ZnS₂), or the like, or combinations of these materials. The antireflection layer 45 may have a thickness from 10 to 100 nanometers.

The solar cell 5 also includes front contacts 30, which may be formed from conductive materials such as silver (Ag). Generally, for silicon and other substrates, silver may be used to form front contacts on a surface of the substrate when the front surface layer is doped n-type. To decrease recombination where the metal directly contacts silicon and limit the proportion of metal covering the surface of the substrate, the front contacts 30 may be configured as point or line contacts (sometimes called “local contacts”). In particular, the front contacts 30 may be formed by screen-printing the silver on the front surface of the antireflection layer 45. As described in greater detail below, the front contacts 30 may be in electrical communication with bus bars to facilitate electrical connections to the front surface of the solar cell 5.

In addition, for the front contacts 30, silver may be selected because of its high electrical conductivity to limit shadowing effects that can lower solar cell efficiency. In embodiments comprising a selective front surface layer, the front contacts 30 may also be aligned with the heavily doped regions 15 of the selective front surface layer. In accordance with certain embodiments, the front passivation layer 40 and the antireflection layer 45 may be disposed on the front surface of the doped regions 15, 20 of the selective front surface layer prior to forming the front contacts 30. In this case, the front contacts 30 may physically penetrate the front passivation layer 40 and the antireflection layer 45 to make contact with the underlying regions of the selective front surface layer.

According to certain embodiments, the back contact 35 may be formed on the back surface 9 of the substrate using screen-printed pastes. The paste used to form the back contact 35 may be an aluminum paste, for example an aluminum paste chosen to have high cohesion after firing. In some embodiments, the screen-printed paste may be applied to cover nearly the entire back surface 9 of the substrate, for example the paste may not be printed over a narrow border near the edges of the wafer approximately 1 mm wide. In accordance with certain embodiments, firing of the screen-printed paste may form the back contact 35 and back surface layer 50. In some embodiments, the back contact 35 may physically penetrate an optional rear passivation layer during firing. In other embodiments, local back contacts may be formed through one or more holes or vias through a rear passivation layer, and the remainder of the back contact 35 may not penetrate or consume the rear passivation layer, for example when the paste used to form the back contact 35 is fritless.

As noted above, due to the firing of the back contact 35, a back surface layer 50, such as an aluminum-doped p⁺ silicon layer, is formed by liquid phase epitaxial regrowth in the region between the base layer 10 and the back contact 35. In the illustrated embodiment, the back contact 35 may make electrical contact with the back surface layer 50. The back contact 35 may be composed at least partially of an aluminum-silicon eutectic composition. In embodiments where the conductivity type of the back surface layer 50 is opposite the conductivity type of the base layer 10, for example where the base layer is doped to be n-type and where the back surface layer 50 comprises a sufficient amount of aluminum to be doped p-type, a p-n junction 60 may be formed at the interface between the base layer 10 and the back surface layer 50. According to these embodiments, the back surface layer 50, such as the aluminum-doped p⁺ silicon layer, may act as an emitter layer. Furthermore, the method may reduce the possibility of the back contact 35 shunting the p-n junction because the aluminum of the back contact 35 is the source of the p-type dopant for forming the back surface layer 50, which in turn forms the p-n junction 60 at the interface of the base layer 10 and the back surface layer 50.

The back contact 35 may also serve as a reflective back layer for the solar cell 5. Having a reflective back layer provides a reflective surface to return incident light reaching the back to the substrate where it can generate free charge carriers. The thickness of the back contact 35 may be from 5 to 50 micrometers in thickness. The back layer may, in some embodiments, provide a measure of reflectivity.

As will be appreciated from the description herein, the back junction solar cell 5 shown in FIG. 1 is just one embodiment of a solar cell that may be adapted to use the reduced-area bus bars described herein. Indeed, as will be appreciated from the description herein, the reduced-area bus bars described below may be configured for collecting current from contacts on the surfaces of a variety of solar cells, including front junction cells, back junction cells, bifacial cells, and the like. For example, in certain embodiments, various embodiments of the bus bars described herein may be provided on the front and back surfaces of a bifacial heterojunction cell

### Reduced-Area Bus Bar

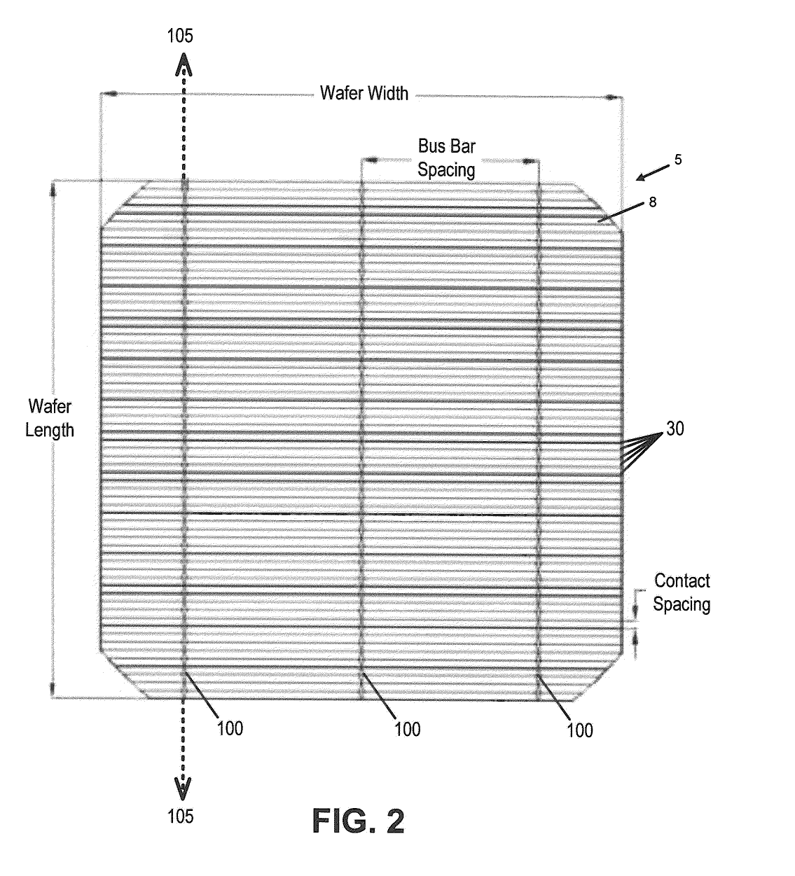

FIG. 2 shows a top view of the front surface 8 of the solar cell 5. As shown in the illustrated embodiment of FIG. 2, the front contacts 30 are oriented laterally and extend across the width of the wafer in a spaced apart relationship to one another. As an example, in one embodiment, the width of the wafer may be approximately 156 mm and the front contacts may be spaced 2.4 mm apart from one another. In such an embodiment, the front contacts themselves may have a width between—for example—approximately 0.02 mm and 0.15 mm (e.g., 0.08 mm).

In the illustrated embodiment, front contacts 30 are in electrical communication with three reduced-area bus bars 100, each of which is oriented longitudinally (e.g., perpendicular to the front contacts 30) and extends along the length of the wafer. As an example, in one embodiment, the length of the wafer may be approximately 153 mm. In particular, as will be appreciated from FIG. 2, each bus bar 100 defines a generally longitudinal axis 105. In addition, the bus bars 100 are oriented generally parallel to one another and are spaced apart from one another. For example, in one embodiment, the bus bars 100 may be spaced 52 mm apart from one another.

According to various embodiments, the bus bars 100 may be formed from an electrically conductive material, such as silver, disposed on the front surface 8 of the wafer. For example, in order to remain in electrical communication with the front contacts 30, various portions of the conductive material forming the bus bars 100 may be disposed over portions of the front contacts 30 on the cell's front surface 8. In this way, the bus bars 100 are able to collect current (i.e., free charge carriers) from the front contacts 30.

As noted above, each of the bus bars 100 is also configured for being soldered to an interconnecting ribbon. In particular, in a solar module, the ribbon may be soldered to bus bars on opposite terminals of adjacent solar cells in order to connect the adjacent cells in series. In order to reduce material usage while providing a solderable connection to the ribbon of sufficient pull strength, each bus bar 100 is configured such that its width generally varies between a first larger width and second smaller width at various points along the respective bus bar's longitudinal axis 105. As described in greater detail below, the wider portions of each bus bar 100 provide regions of high pull strength when the ribbon is soldered to the bus bar 100, while the narrower portions of the bus bar 100 reduce overall material usage in forming the bus bar 100.

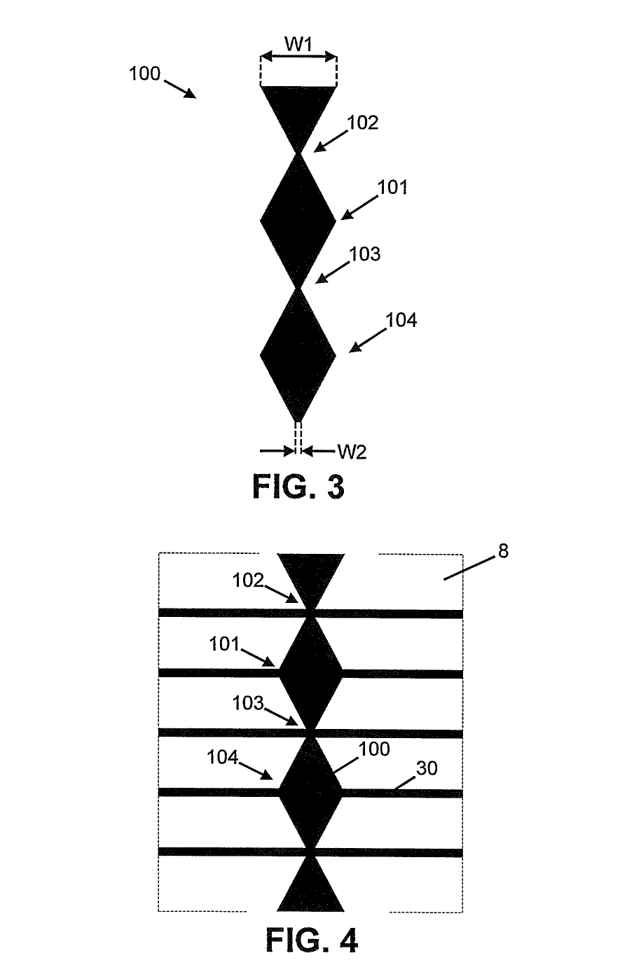

FIG. 3 provides a detailed top view of the profile of one of the bus bars 100 according to one embodiment. In the illustrated embodiment of FIG. 3, the bus bar 100 varies between a first, larger width W1 and a second, smaller width W2 to form a series of continuous, diamond-shaped formations. For example, as shown in FIG. 3, the bus bar 100 is widest at a first portion 101, at which the bus bar has a width W1 (e.g., 1.5 mm). Adjacent the first portion 101, the bus bar 100 narrows to a second portion 102 having a narrower width W2 (e.g., 0.08 mm). On the opposite side of the first portion 101, the bus bar 100 narrows to a third portion 103, at which the bus bar 100 again has the narrower width W2. Adjacent the third portion 103, the bus bar again widens to a fourth portion 104 having the width W1. As will appreciated from FIG. 3, the bus bar's various portions 101, 102, 103, 104 are aligned along (and symmetrical about) the bus bar's longitudinal axis 105 (shown in FIG. 2). In addition, in the illustrated embodiment, the full length of the bus bars 100 have a continuous profile that varies in width as shown in FIG. 3 (e.g., such that the bus bars 100 have repeating portions 102-101-103-104 along the full length of the wafer's top surface 8).

As will be appreciated from the description herein, the dimension of the diamond-patterned bus bar 100 may vary according to various embodiments. For example, in one embodiment, the fourth portion 104 may have a width that is greater than the second and third portions 102, 103, but less than the first portion 101. Likewise, the first portion 101 may have a width that is greater than the second and third portions 102, 103, but less than the fourth portion 104.

In addition, various embodiment of the bus bar 100 may be dimensioned such that the diamond-shaped pattern defined by the bus bar 100 repeats more or less frequently along the length of the bus bar 100. For example, in various embodiments, the spacing between first portion 101 and fourth portion 104 may be relatively short (e.g., 0.05% of the length of the wafer). In other embodiments, the spacing between the first portion 101 and the fourth portion 404 may be relatively long (e.g., 50% of the length of the wafer).

FIG. 4 provides a detailed top view of one of the bus bars 100 on the top surface 8 of the solar cell 5. In the illustrated embodiment of FIG. 4, the bus bar 100 is dimensioned such that every other front contact 30 intersects the wider portions 101, 104 of the bus bar 100, while the remaining front contacts 30 intersect the narrower portions 102, 103 of the bus bar 100. As the bus bar 100 extends continuously along its longitudinal axis 105, current collected form any one of the contacts 30 can be collected and carried through the bus bar 100. According to various other embodiments, however, the bus bar 100 and/or front contacts 30 can be provided in varying dimensions. For example, in one embodiment, each front contact 30 intersects one of the wider portions 101, 104 of the bus bar 100. In other embodiments, every fourth contact 30 intersects one of the wider portions 101, 104 of the bus bar 100.

According to various embodiments, the bus bar 100 is configured such that an interconnecting ribbon (e.g., a metallic copper ribbon coated with tin) may be soldered along the length of the bus bar 100. In such embodiments, the portions of the ribbon soldered to the wider portions 101, 104 of the bus bar 100 will have a strong connection to the bus bar 100 (e.g., as compared to the strength of the ribbon's connection to the narrower portions of the bus bar 100). As has been recognized by the inventors, this is attributable to the larger width W1 of the bus bar's portions 101, 104. For example, testing of certain bus bar embodiments having the profile shown in FIG. 3 have achieved a pull strength in excess of 4 Newtons per millimeter. As such, a strong connection between the ribbon and the bus bar 100 may be achieved with the bus bar profile shown in FIG. 3 due to the intermittent wide portions 101, 104 of the bus bar 100.

In addition to the high pull strength, the profile of the bus bar 100 also enables a reduction in material usage due to the narrower portions 102, 103 of the bus bar 100. For example, in the illustrated embodiment, the bus bar 100 can be formed from 50% less silver paste than a linear bus bar having the width W1. This reduction in material usage has a number of advantages. First, in certain embodiments, reducing the usage of expensive bus bar material (e.g., silver) reduces the overall cost of the solar cell 5 as the cell's bus bars can be formed from less material without sacrificing high levels of electrical and mechanical performance. This can be particularly advantageous for solar cells utilizing exceptionally high cost materials to form bus bars (e.g., specially formulated low temperature Ag pastes). Second, the ability to reduce the amount of material needed to form individual bus bars can also enable improvements in electrical and mechanical cell performance. For example, in certain embodiments, reducing the material required to form a single bus bar may enable additional bus bars to be formed on the surface a solar cell without increasing the overall cost of the cell (e.g., two bus bars 100 might be formed using the same amount of material necessary to form a single linear bus bar). In such embodiments, the additional bus bars can reduce fill factor losses and improve the overall performance of the cell without leading to increased costs.

As will be appreciated from the description herein, the bus bar 100 described above may be used on the surfaces of various solar cells and in various configurations. For example, any number of bus bars 100 may be provided on the top surface 8 of the solar cell 5 (e.g., one, two, three, four, etc. bus bars 100 provided on the top surface 8 in a manner analogous to that shown in FIG. 2). Additionally, the bus bars 100 may be provided on the back surface of various solar cells (e.g., on the back surface of solar cells having back contacts analogous to those described above, such as a bifacial solar cell).

### Alternative Bus Bar Embodiments

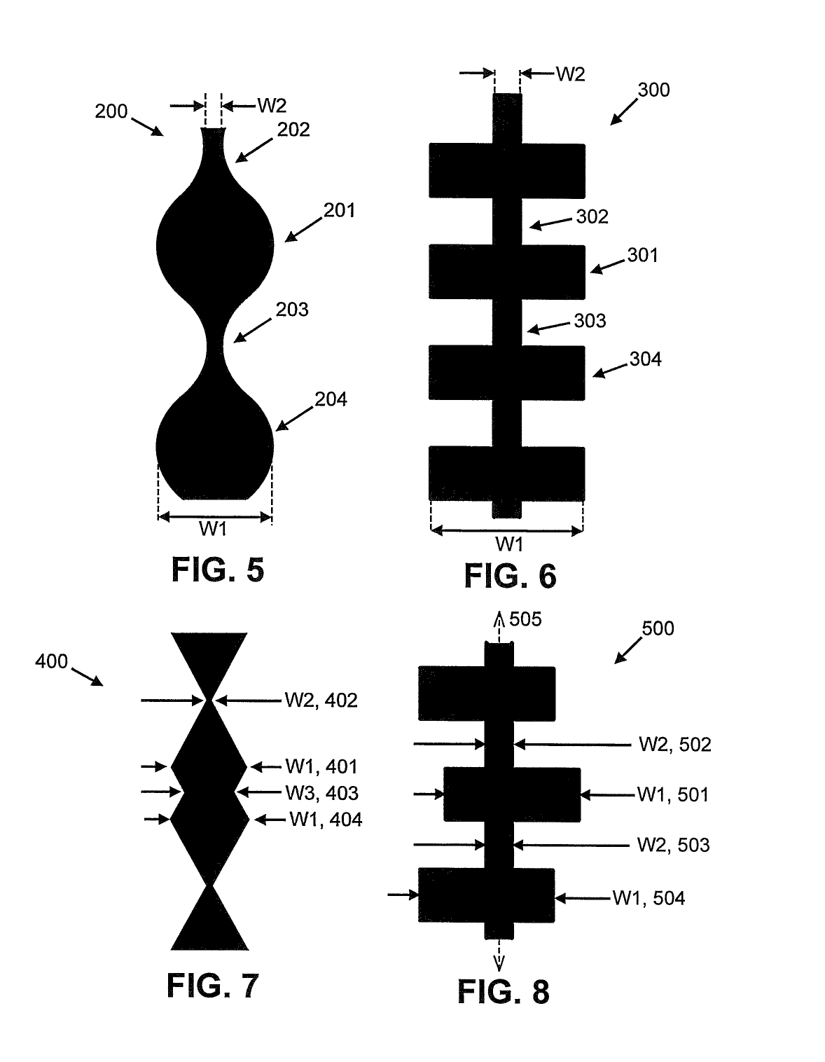

According to various embodiments, other bus bars having varying widths are contemplated as being within the scope of the present invention. For example, FIG. 5 illustrates a bus bar 200 according to another embodiment of the present invention. In the illustrated embodiment of FIG. 5, the bus bar 200 varies between a first, larger width W1 and a second, smaller width W2 to form a series of continuous, rounded formations. For example, as shown in FIG. 5, the side edges of the bus bar 200 are generally curvilinear (e.g., defining opposing, out-of-phase sinusoidal curves). In the illustrated embodiment, the bus bar 200 is widest at a first portion 201, at which the bus bar has a width W1 (e.g., 1.5 mm). Adjacent the first portion 201, the bus bar 200 narrows to a second portion 202 having a narrower width W2 (e.g., 0.08 mm). On the opposite side of the first portion 201, the bus bar 200 narrows to a third portion 203, at which the bus bar again has the narrower width W2. Adjacent the third portion 203, the bus bar 200 again widens to a fourth portion 204 having the width W1. As will be appreciated from FIG. 5, the bus bar's various portions 201, 202, 203, 204 are aligned along (and symmetrical about) a longitudinal axis such that the bus bar 200 defines a continuous profile that repeatedly varies in width.

FIG. 6 illustrates a bus bar 300 according to yet another embodiment of the present invention. In the illustrated embodiment of FIG. 6, the bus bar 300 varies between a first, larger width W1 and a second, smaller width W2 to form a series of lateral segments connected by a central linear formation. For example, as shown in FIG. 6, the bus bar 300 is widest at a first portion 301, at which the bus bar has a width W1 (e.g., 1.5 mm). This first portion 301 represents one of the repeating laterally oriented segments. Adjacent the first portion 301, the bus bar 300 narrows to a second portion 302 having a narrower width W2 (e.g., 0.08 mm). On the opposite side of the first portion 301, the bus bar 300 narrows to a third portion 303, at which the bus bar again has the narrower width W2. Adjacent the third portion 303, the bus bar 300 again widens to a fourth portion 304 defining another lateral segment of width W1. As shown in FIG. 6, the second and third portions 302, 303 constitute the aforementioned central linear formations that link the lateral segments defined by the wider portions 301, 304. In addition, as will be appreciated from FIG. 6, the bus bar's various portions 301, 302, 303, 304 are aligned along (and symmetrical about) a longitudinal axis such that the bus bar 300 defines a continuous profile that repeatedly varies in width.

FIG. 7 illustrates a bus bar 400 according to yet another embodiment of the present invention. In the illustrated embodiment of FIG. 7, the bus bar 400 varies between a first, larger width W1 and a second, smaller width W2 to form a series of diamond-like formations. However, as shown in FIG. 7, portions of the bus bar 400 narrow to a medial width W3 (smaller than W1, but larger than W2) at various intermediate portions. For example, the bus bar 400 is widest at a first portion 401, at which the bus bar has a width W1 (e.g., 1.5 mm). Adjacent the first portion 401, the bus bar 400 narrows to a second portion 402 having a narrower width W2 (e.g., 0.08 mm). On the opposite side of the first portion 401, the bus bar 400 narrows to a third portion 403, at which the bus bar again has a medial width W3 that is wider than the width W1 but narrower than the width W2. Adjacent the third portion 403, the bus bar 400 again widens to a fourth portion 404 having the width W1. As such, the bus bar 400 continuously varies between the widths W1 and W2, but also includes certain medial portions having the width W3. In addition, as will be appreciated from FIG. 7, the bus bar's various portions 401, 402, 403, 404 are aligned along (and symmetrical about) a longitudinal axis such that the bus bar 400 defines a continuous profile that repeatedly varies in width.

FIG. 8 illustrates a bus bar 500 according to yet another embodiment of the present invention. In the illustrated embodiment of FIG. 8, the bus bar 500 varies between a first, larger width W1 and a second, smaller width W2 to form a series of laterally oriented segments connected by a central linear formation. For example, as shown in FIG. 8, the bus bar 500 is widest at a first portion 501, at which the bus bar has a width W1 (e.g., 1.5 mm). This first portion 501 represents one of the repeating laterally oriented strips. Adjacent the first portion 501, the bus bar 500 narrows to a second portion 502 having a narrower width W2 (e.g., 0.08 mm). On the opposite side of the first portion 501, the bus bar 500 narrows to a third portion 503, at which the bus bar again has the narrower width W2. Adjacent the third portion 503, the bus bar 500 again widens to a fourth portion 504 having the width W1. As shown in FIG. 8, the second and third portions 502, 503 constitute the aforementioned central linear formation that links the lateral strips defined by the wider portions 501, 504. In addition, in the illustrated embodiment of FIG. 8, the various lateral segments defined by the first portions 501 are not aligned with one another (e.g., such that adjacent wide portions 501, 504 are alternatingly offset to the left or right from the bus bar's longitudinal axis 505). However, as will be appreciated from FIG. 8, the bus bar 500 is nevertheless aligned along its longitudinal axis 505 such that the bus bar 500 defines a continuous profile that repeatedly varies in width.

In addition, various embodiment of the bus bars 200, 300, 400, 500 may be dimensioned such that the patterns defined by the bus bars repeat more or less frequently along the length of the bus bars. For example, in various embodiments, the spacing between the first portions 201, 301, 401, 501 and fourth portions 204, 304, 404, 504—respectively—may be relatively short (e.g., 0.05% of the length of the wafer). In other embodiments, the spacing between the first portions 201, 301, 401, 501 and fourth portions 204, 304, 404, 504—respectively—may be relatively long (e.g., 50% of the length of the wafer).

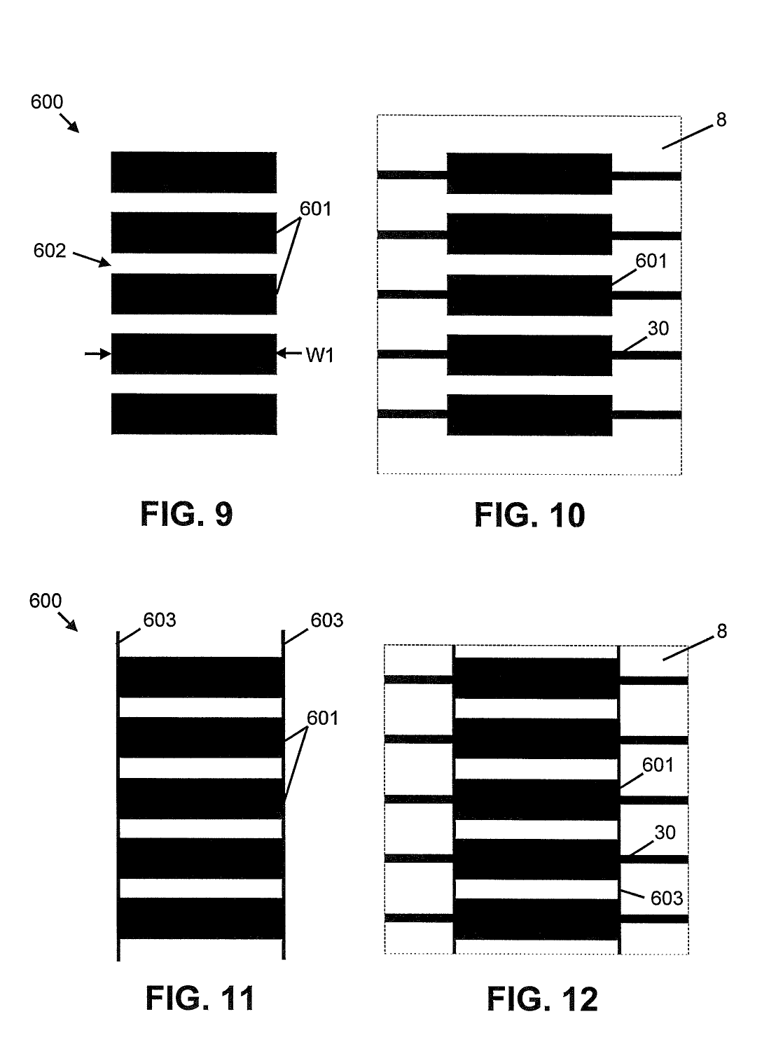

FIG. 9 illustrates a bus bar 600 according to yet another embodiment of the present invention. In the illustrated embodiment of FIG. 9, the bus bar 600 defines a series of laterally oriented segments having a width W1. For example, as shown in FIG. 9, the bus bar 300 is widest at a first portion 601, at which the bus bar has the width W1 (e.g., 1.5 mm). This first portion 601 represents one of the repeating laterally oriented segments (or strips) that comprise the bus bar 600. As shown in FIG. 6, the bus bar's lateral segments (601) are spaced apart from one another by portions 602 where no conductive material has been disposed. As such, various embodiments the bus bar 600 can be formed from less silver paste than a linear bus bar having the width W1 (e.g., 50% less). As will be appreciated from FIG. 6, the bus bar's laterally oriented segments (601) are aligned along (and symmetrical about) a longitudinal axis. In addition, while the laterally oriented segments (601) shown in FIG. 9 are generally rectangular, the strips may be provided with a different profile according to various other embodiments (e.g., where each strip is ovular). In addition, in various other embodiments, the segments 601 may be longitudinally oriented (e.g., such that each segment's length in the direction of the bus bar's longitudinal axis is greater than its width).

FIG. 10 provides a detailed top view of the bus bar 600 on the top surface 8 of a solar cell. In the illustrated embodiment of FIG. 10, the bus bar 600 is dimensioned such that every front contact 30 intersects the first portions 601 of the bus bar 100. As shown in the embodiment of FIG. 10, the bus bar 600 is not continuous. However, when an interconnecting ribbon is soldered along the length of the bus bar 600, the ribbon renders the various portions 601 of the bus bar 600 in electrical communication with one another such that the bus bar and ribbon are able to collect current from all of the contacts 30.

FIG. 11 illustrates another embodiment of the bus bar 600 in which the bus bar 600 includes longitudinal connecting lines 603 that extend along the lateral sides of the bus bar's first portions 601. According to various embodiments, the longitudinal connecting lines 603 render the lateral segments defining the first portions 601 in electrical communication with one another (e.g., even where an interconnecting ribbon is not soldered to one or more portions of the bus bar 600). In this way, the bus bar 600 of FIG. 11 is formed continuously along surface of the solar cell.

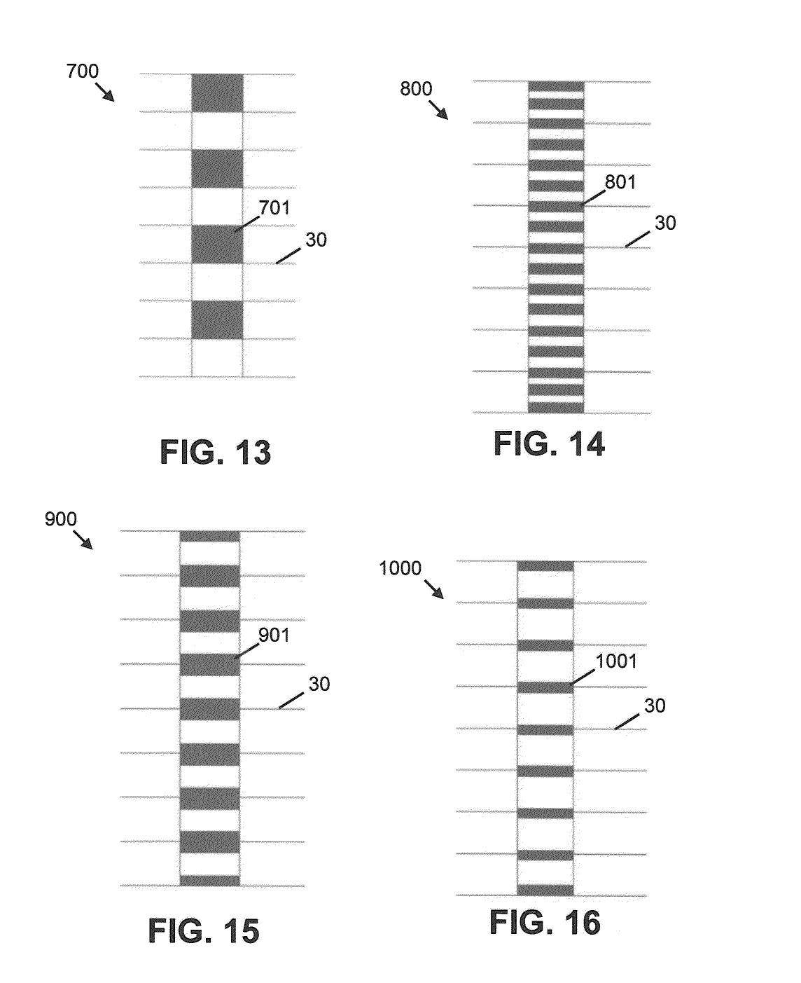

FIG. 12 shows a detailed top view of this embodiment of the bus bar 600 on the top surface of a solar cell. As shown in FIG. 12, the bus bar 600 is dimensioned such that every front contact 30 intersects the first portions 601 of the bus bar 100. However, according to various other embodiments, the dimensions of the bus bar 600 may be altered while according to various embodiments. For example, FIG. 13 illustrates an embodiment of a bus bar 700 in which a pair of electrical contacts 30 intersect each of the bus bar's lateral segments (or strips) 701. In contrast, FIG. 14 illustrates an embodiment of a bus bar 800 in which the every other electrical contact 30 intersects the bus bar's lateral segments 801. However, the contacts 30 not intersecting one of the lateral segments 801 are kept in electrical communication with bus bar 800 via the longitudinal connecting lines. Finally, FIGS. 15 and 16 show embodiments of bus bars 900, 1000 in which the length of each of the bus bar's lateral segments 901, 1001 differ.

In addition, various embodiments of the bus bars 600, 700, 800, 900, 1000 may be dimensioned such that the spacing between the segments defined by the bus bars may differ. For example, in various embodiments, the spacing between the bus bar segments 601, 701, 801, 901, 1001—respectively—may be relatively short (e.g., 0.05% of the length of the wafer). In other embodiments, the spacing between the bus bar segments 601, 701, 801, 901, 1001—respectively—may be relatively long (e.g., 50% of the length of the wafer).

As will be appreciated from the description herein, the bus bars 200, 300, 400, 500, 600, 700, 800, 900, and 1000 described above may be used on the surfaces of various solar cells and in various configurations (e.g., such that any appropriate number of bus bars may be provided on the front and/or back surfaces of the cell). According to various embodiments, the bus bars 200, 300, 400, 500, 600, 700, 800, 900, and 1000 are each configured such that an interconnecting ribbon (e.g., a metallic copper ribbon coated with tin) may be soldered along the length of each respective bus bar. In such embodiments, the portions of the ribbon soldered to the wider portions (201, 301, 401, 501, 601, 701, 801, 901, 1001) of the bus bars will have a strong connection to each bus bar (e.g., as compared to the strength of the ribbon's connection to the narrower, or spaced, portions of the bus bars). As each of the bus bars 200, 300, 400, 500, 600, 700, 800, 900, and 1000 vary in width (or have segments spaced from one another), a strong connection between the ribbon and the bus bar 100 may be achieved while also reducing material usage in the bus bars (e.g., the volume of silver used to form each bus bar). In this way, the bus bars 200, 300, 400, 500, 600, 700, 800, 900, and 1000 also enable a reduction in the overall cost of their associated solar cells without sacrificing high levels of electrical and mechanical performance.

### Conclusion

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A solar cell having a front surface and a back surface, the solar cell comprising:
a semiconductor wafer;
one or more contacts positioned on at least one of the front surface and back surface of the solar cell, the contacts being in electrical communication with the solar cell; and
at least one bus bar disposed on the at least one of the front surface and back surface in electrical communication with the one or more contacts and configured for collecting current from the one or more contacts;
wherein the bus bar is oriented along a generally longitudinal axis, wherein the width of the bus bar varies at points along the longitudinal axis, and wherein the bus bar defines:
a first portion having a first width;
a second portion positioned adjacent the first portion, the second portion having a second width that is less than the first width;
a third portion positioned adjacent the first portion opposite the second portion, the third portion having a third width that is less than the first width; and
a fourth portion positioned adjacent the third portion, the fourth portion having a fourth width that is greater than the third width.

2. The solar cell of claim 1, wherein the at least one bus bar is formed continuously along its longitudinal axis.

3. The solar cell of claim 1, wherein the first width is equal to the widest portion of the bus bar and the second width is equal to the narrowest portion of the bus bar.

4. The solar cell of claim 1, wherein the third width is equal to the second width.

5. The solar cell of claim 1, wherein the third width is greater than the second width.

6. The solar cell of claim 1, wherein the fourth width is equal to the first width.

7. The solar cell of claim 1, wherein the bus bar has a diamond patterned profile defining a series of two or more linked diamond-shaped portions of the bus bar, wherein the bus bar's first portion defines a medial region of a first diamond-shaped portion, and wherein the bus bar's second and third portions define points at which adjacent diamonds-shaped portions intersect the first diamond-shaped portion.

8. The solar cell of claim 1, wherein the first portion and fourth portion are spaced by a distance that is 50% or less of the length of the semiconductor wafer.

9. The solar cell of claim 1, wherein lateral sides of the bus bar defining the bus bar's varying width are curvilinear.

10. The solar cell of claim 1, wherein the bus bar is symmetrical about its longitudinal axis.

11. The solar cell of claim 1, wherein the bus bar's first portion intersects at least one of the contacts.

12. The solar cell of claim 11, wherein the bus bar's second portion intersects at least one of the contacts.

13. The solar cell of claim 1, wherein the contacts are oriented generally perpendicular to the bus bar's longitudinal axis.

14. The solar cell of claim 1, wherein the at least one bus bar is configured for being soldered along its length to a metallic interconnecting ribbon.

15. A solar cell having a front surface and a back surface, the solar cell comprising:
a semiconductor wafer;
a plurality of contacts positioned on at least one of the front surface and back surface of the solar cell in a spaced-apart relationship, the contacts being in electrical communication with the solar cell; and
at least one bus bar disposed on the at least one of the front surface and back surface in electrical communication with the one or more contacts and configured for collecting current from the one or more contacts;
wherein the bus bar is oriented along a generally longitudinal axis and comprises a plurality of bus bar segments disposed in a spaced-apart relationship along the longitudinal axis.

16. The solar cell of claim 15, wherein the segments are laterally oriented with respect to the longitudinal axis.

17. The solar cell of claim 15, wherein the segments are in electrical communication with one another.

18. The solar cell of claim 17, wherein the segments are electrically connected by one or more longitudinal connecting lines.

19. The solar cell of claim 18, wherein the one or more longitudinal connecting lines comprise a pair of connecting lines positioned along lateral sides of the segments.

20. The solar cell of claim 15, wherein the segments are rectangular.

21. The solar cell of claim 15, wherein each of the segments intersects at least one of the contacts.

22. The solar cell of claim 15, wherein each of the segments intersects two or more of the contacts.

23. The solar cell of claim 15, wherein segments are defined symmetrically about the bus bar's longitudinal axis.

24. The solar cell of claim 15, wherein the at least one bus bar is configured for being soldered to a metallic interconnecting ribbon.
